(19) United States
(12) Patent Application Publication
(10) Pub. No.: US 2018/0234596 A1
(43) Pub. Date: Aug. 16, 2018

(54) CAMERA MODULE PROTECTION STRUCTURE

(71) Applicant: ASIA VITAL COMPONENTS CO., LTD., New Taipei City (TW)

(72) Inventors: Ping-Huang Yang, New Taipei City (TW); Xin-Lian Cheng, New Taipei City (CN); Xing-Xing Wang, New Taipei City (CN)

(21) Appl. No.: 15/430,545

(22) Filed: Feb. 13, 2017

(51) Int. Cl. H04N 5/225; H05K 1/18

(52) U.S. Cl. CPC H04N 5/2252; H04N 5/2254; H05K 2201/10227; H05K 2201/10121; H05K 1/181

(57) ABSTRACT

A camera module protection structure includes a circuit board, a case and a camera device. The case is disposed on the circuit board. At least one side of the case is formed with a securing section. The case is formed with a receiving space in a position corresponding to the securing section. The camera device is correspondingly disposed in the receiving space. According to the structural design of the camera module protection structure, the securing section of the case is able to enhance the structural strength of the entire camera module and greatly lower the damage ratio of the camera module and prevent the circuit board from being easily broken off or damaged in assembling process of the camera module.

### BACKGROUND OF THE INVENTION

### 1. Field of the Invention

The present invention relates generally to a camera module protection structure, and more particularly to a camera module protection structure, which is able to enhance the structural strength of the entire camera module and greatly lower the damage ratio of the camera module.

### 2. Description of the Related Art

Along with the advance of sciences and technologies, camera modules have been more and more popularly applied to electronic products such as notebooks and mobile phones. There is a trend to develop lighter and thinner electronic products. Therefore, the total thickness, weight and quality of the camera module inbuilt in the electronic products are very strictly required. Accordingly, it has become a critical topic in this field how to further reduce the total thickness and weight and enhance the quality of the camera module.

Please refer to FIG. 1, which is a perspective assembled view of a conventional camera module 1. The conventional camera module 1 is composed of a circuit board 10, a case 11, a camera device 12 and a connector 13. The case 11 and the camera device 12 are mounted on the circuit board 10. As shown in FIG. 1, a gap 14 exists between the case 11 and the camera device 12 in the assembling and manufacturing process. The circuit board 10 is apt to break off due to the gap 14. In addition, in the transfer process of the camera module 1, the camera device 12 or the entire camera module 1 is often damaged due to external force collision. Therefore, as a whole, the conventional camera module 1 has relatively poor structural strength.

According to the above, the conventional camera module has the following shortcomings:
1. The structural strength of the conventional camera module is relatively poor.
2. The damage ratio of the conventional camera module is higher.
3. The circuit board is apt to break off and damage in the assembling process of the camera module.

### SUMMARY OF THE INVENTION

It is therefore a primary object of the present invention to provide a camera module protection structure, which is able to enhance the structural strength of the entire camera module.

It is a further object of the present invention to provide the above camera module protection structure, which is able to greatly lower the damage ratio of the camera module.

It is still a further object of the present invention to provide the above camera module protection structure, which is able to prevent the circuit board from being easily broken off or damaged in assembling process of the camera module.

To achieve the above and other objects, the camera module protection structure of the present invention includes a circuit board, a case and a camera device. The case is disposed on the circuit board. At least one side of the case is formed with a securing section. The case is formed with a receiving space in a position corresponding to the securing section. The camera device is correspondingly disposed in the receiving space. The camera device has a lens and a rest seat body. The lens is correspondingly received in the rest seat body.

According to the structural design of the present invention, the securing section of the case is able to effectively prevent the circuit board from being broken off or functionally damaged in assembling process. Moreover, the securing section is able to greatly lower the damage ratio of the camera device and the camera module due to external force collision in the transfer and manufacturing process. Also, the securing section can enhance the structural strength of the entire camera module.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective assembled view of a conventional camera module;

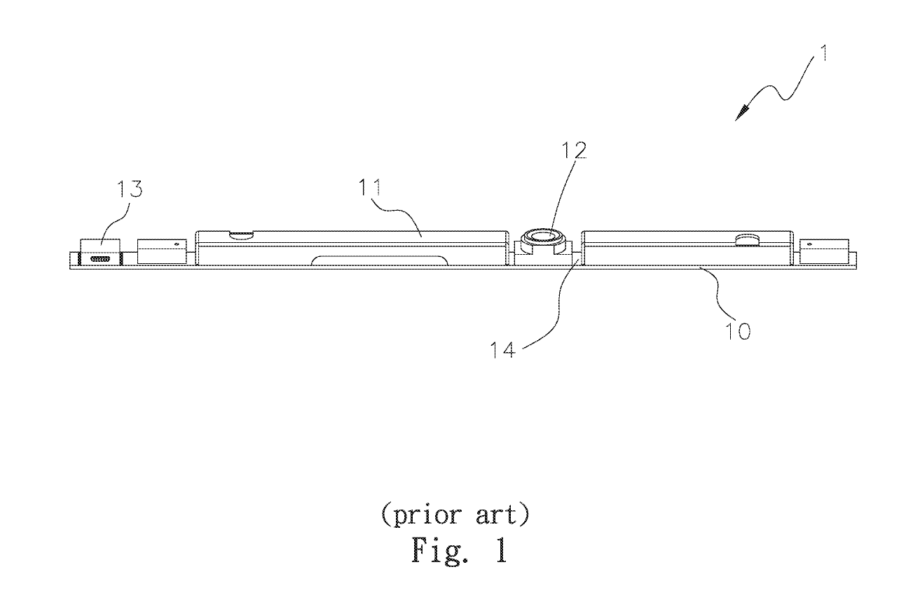

FIG. 2A is a perspective exploded view of a first embodiment of the camera module protection structure of the present invention;

FIG. 2B is a perspective assembled view of the first embodiment of the camera module protection structure of the present invention;

FIG. 3A is a perspective exploded view of a second embodiment of the camera module protection structure of the present invention;

FIG. 3B is a perspective assembled view of the second embodiment of the camera module protection structure of the present invention;

FIG. 4A is a perspective exploded view of a third embodiment of the camera module protection structure of the present invention; and

FIG. 4B is a perspective assembled view of the third embodiment of the camera module protection structure of the present invention.

### DETAILED DESCRIPTION OF THE PREFERRED EMBODIMENTS

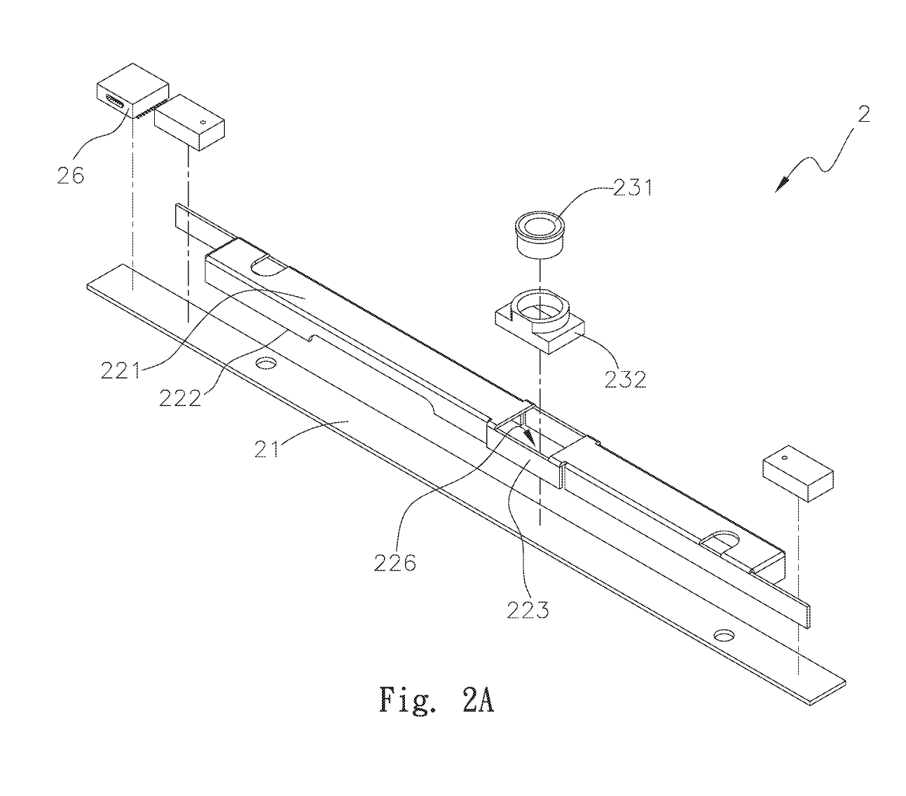

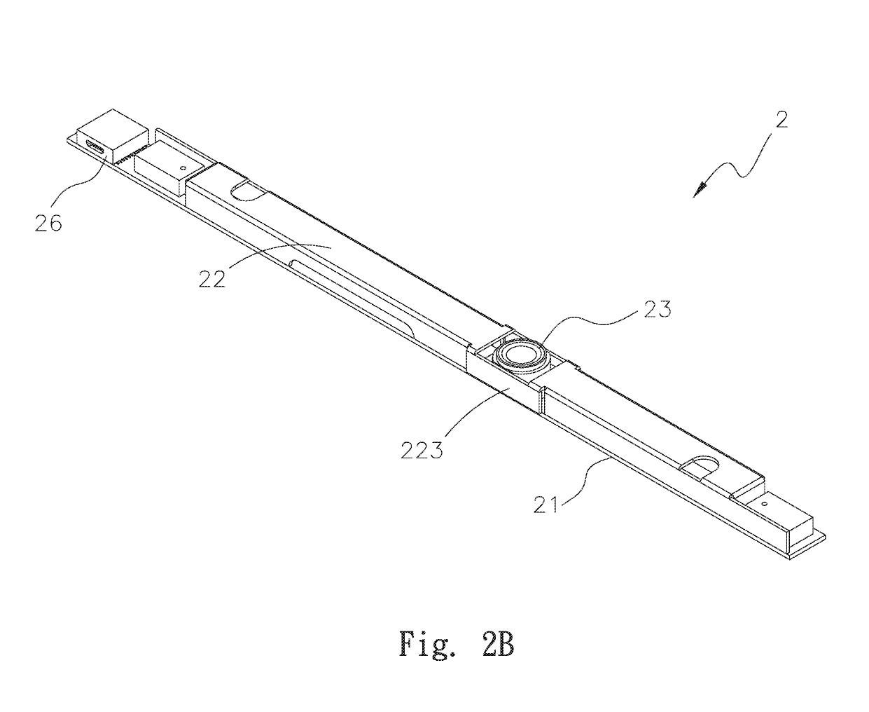

Please refer to FIGS. 2A and 2B. FIG. 2A is a perspective exploded view of a first embodiment of the camera module protection structure of the present invention. FIG. 2B is a perspective assembled view of the first embodiment of the camera module protection structure of the present invention. According to the first embodiment, the camera module protection structure of the present invention includes a circuit board 21, a case 22 and a camera device 23. The case 22 has an upper side 221 and a lower side 222. The lower side 222 is correspondingly attached to one side of the circuit board 21. At least one side of the case 22 is formed with a securing section 223. The case 22 is further formed with a receiving space 226 in a position corresponding to the securing section 223. The camera device 23 is correspondingly disposed in the receiving space 226. The camera device 23 has a lens 231 and a rest seat body 232. The lens 231 is correspondingly received in the rest seat body 232.

In this embodiment, the case 22 is an integrally formed structure. In other words, the structure of the securing section 223 is a part of the case 22.

In addition, in a preferred embodiment, the camera module 2 further has a connector 26. The connector 26 is disposed on the circuit board 21 and connectable to a circuit of an electronic apparatus (not shown).

According to the above structural design of the present invention, the securing section 223 is formed on at least one side of the case 22. The securing section 223 is able to effectively prevent the circuit board 21 from being broken off or functionally damaged in assembling process. Moreover, the securing section 223 is able to greatly lower the damage ratio of the camera device 23 and the camera module 2 due to external force collision in the transfer and manufacturing process. Therefore, the securing section 223 achieves the effect of enhancement of the structural strength of the entire camera module 2.

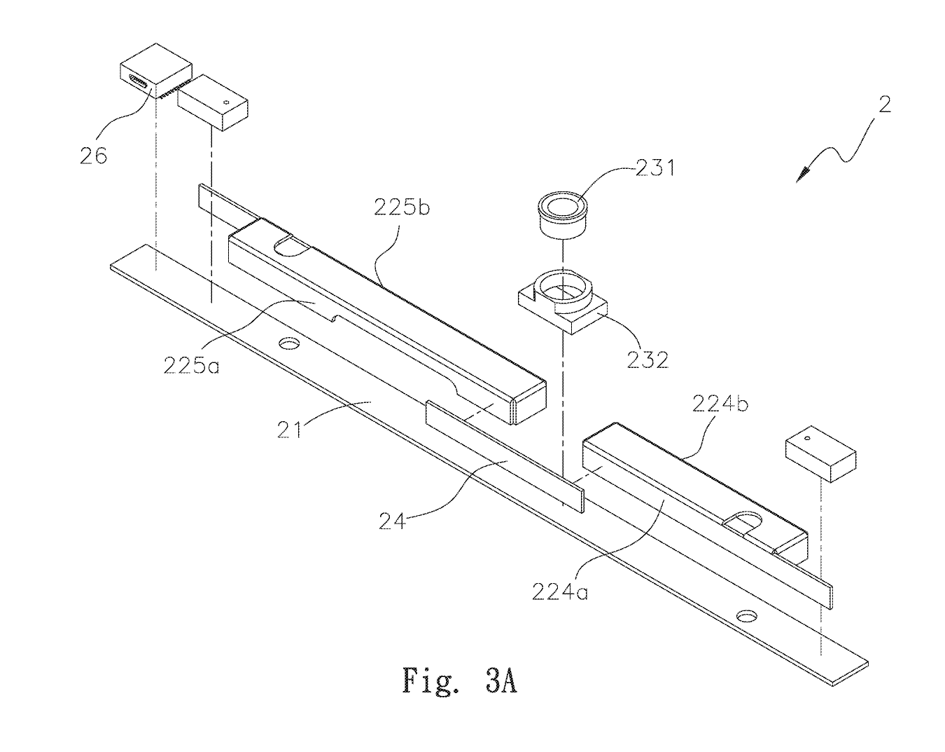

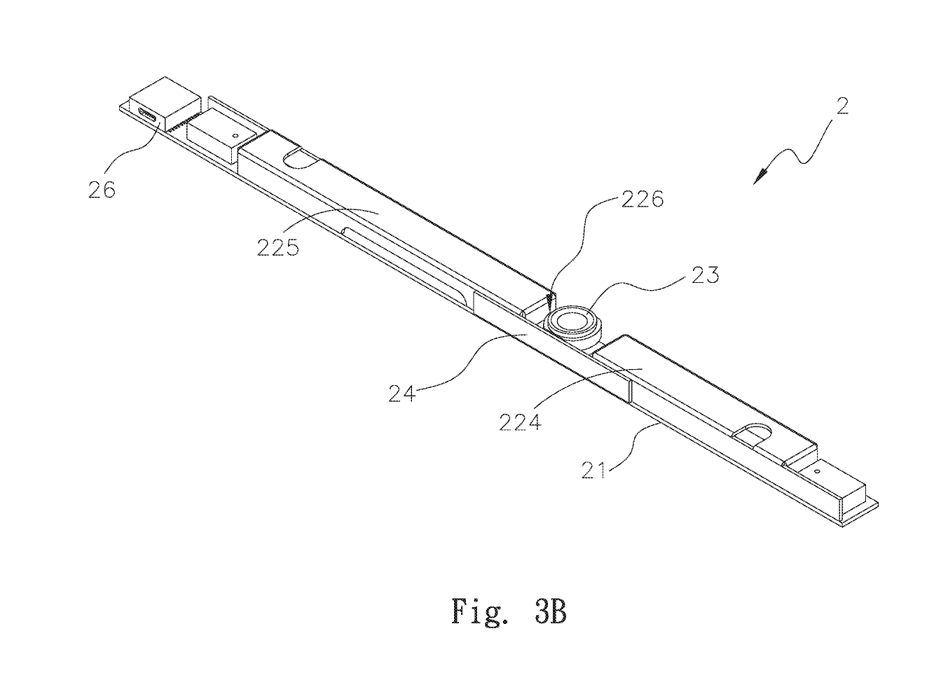

Please now refer to FIGS. 3A and 3B as well as FIG. 2B. FIG. 3A is a perspective exploded view of a second embodiment of the camera module protection structure of the present invention. FIG. 3B is a perspective assembled view of the second embodiment of the camera module protection structure of the present invention. The second embodiment is partially identical to the first embodiment in component and relationship between the components and thus will not be repeatedly described hereinafter. The second embodiment is mainly different from the first embodiment in that the case 22 further has a first case cover 224 and a second case cover 225. The first case cover 224 has a first side 224a and a second side 224b respectively formed on two sides of the first case cover 224. The first side 224a is opposite to the second side 224b. The second case cover 225 has a third side 225a and a fourth side 225b respectively formed on two sides of the second case cover 225. The third side 225a is opposite to the fourth side 225b. The camera module 2 further has at least one first securing plate 24 correspondingly disposed on one side of the case 22 in adjacency to the receiving space 226. The first securing plate 24 is connected with the first side 224a of the first case cover 224 and the third side 225a of the second case cover 225. The connection manner of the first securing plate 24 with the first and third sides 224a, 225a can be riveting or adhesion. In other words, in this embodiment, the first securing plate 24 is employed instead of the securing section 223 of the first embodiment. The first securing plate 24 is mounted on the case 22 in a position in adjacency to the camera device 23. This can achieve the same effect of the first embodiment.

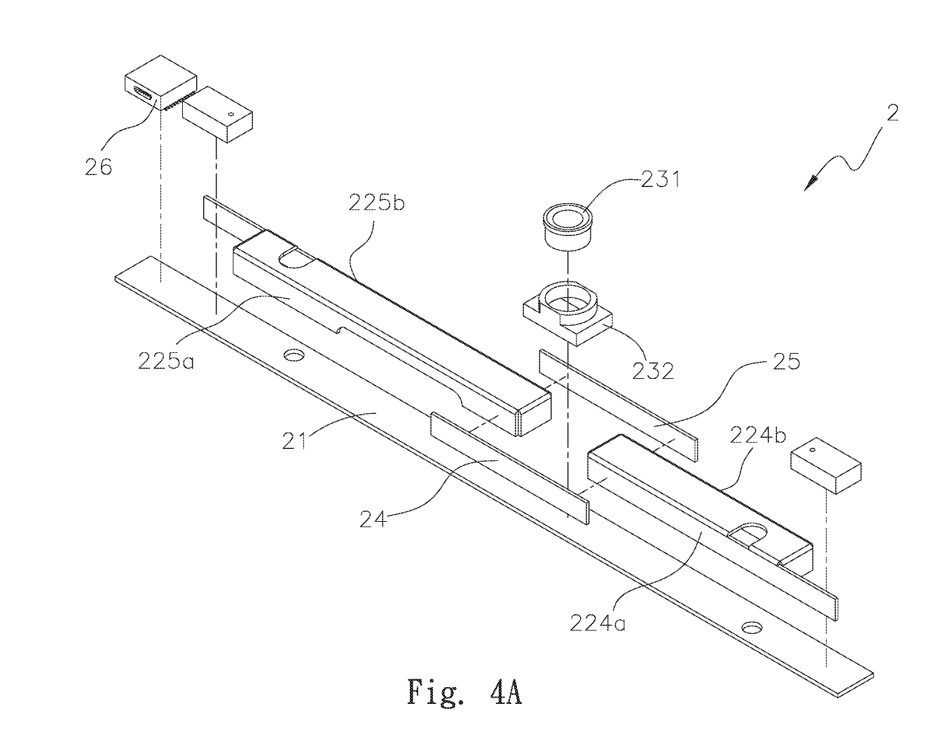

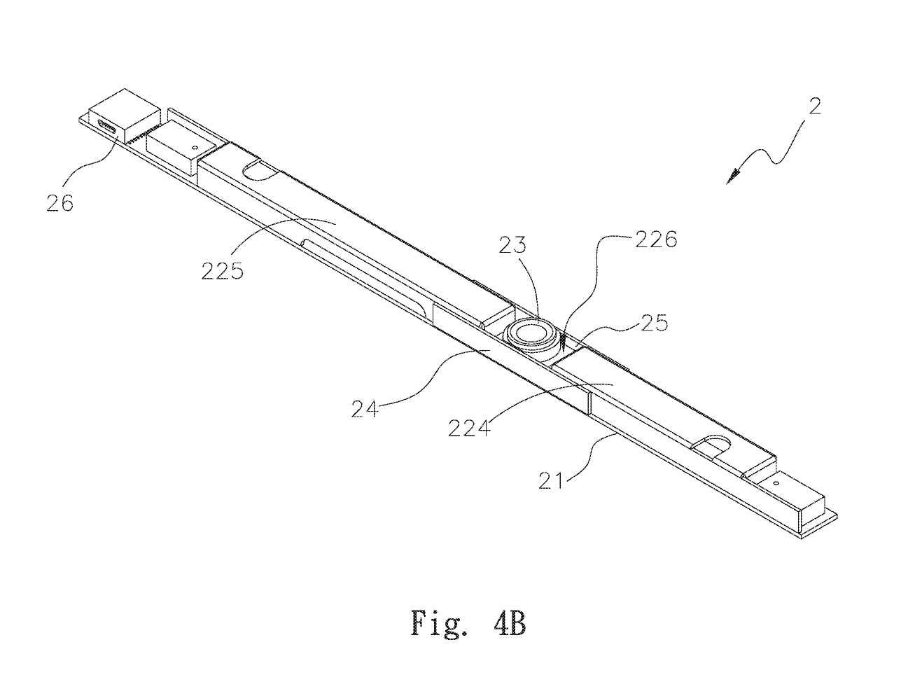

Please now refer to FIGS. 4A and 4B as well as FIG. 2B. FIG. 4A is a perspective exploded view of a third embodiment of the camera module protection structure of the present invention. FIG. 4B is a perspective assembled view of the third embodiment of the camera module protection structure of the present invention. The third embodiment is partially identical to the first embodiment in component and relationship between the components and thus will not be repeatedly described hereinafter. The third embodiment is mainly different from the first embodiment in that the camera module further has at least one second securing plate 25 correspondingly disposed on the other side of the case 22 in adjacency to the receiving space 226. The second securing plate 25 is connected with the second side 224b of the first case cover 224 and the fourth side 225b of the second case cover 225. The connection manner of the second securing plate 25 with the second and fourth sides 224b, 225b can be riveting or adhesion. In other words, in this embodiment, in addition to the first securing plate 24 of the second embodiment, the second securing plate 25 is further employed. The first and second securing plates 24, 25 are respectively mounted on two sides of the case 22 in a position in adjacency to the camera device 23. This can achieve the same effect of the first embodiment.

In conclusion, in comparison with the conventional camera module, the present invention has the following advantages:
1. The structural strength of the entire camera module is enhanced.
2. The damage ratio of the entire camera module is greatly lowered.
3. The circuit board is prevented from being broken off or damaged in assembling process of the camera module.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

1. A camera module protection structure comprising:
a circuit board;
a case disposed on the circuit board, at least one side of the case being formed with a securing section, the case being formed with a receiving space in a position corresponding to the securing section; and
a camera device correspondingly disposed in the receiving space, the camera device having a lens and a rest seat body, the lens being correspondingly received in the rest seat body.

2. The camera module protection structure as claimed in claim 1, wherein the case has an upper side and a lower side, the lower side being correspondingly attached to one side of the circuit board.

3. The camera module protection structure as claimed in claim 1, wherein the case is an integrally formed structure.

4. The camera module protection structure as claimed in claim 1, wherein the case further has a first case cover and a second case cover, the first case cover having a first side and a second side respectively formed on two sides of the first case cover, the second case cover having a third side and a fourth side respectively formed on two sides of the second case cover.

5. The camera module protection structure as claimed in claim 4, further comprising at least one first securing plate correspondingly disposed on one side of the case in adjacency to the receiving space, the first securing plate being connected with the first side of the first case cover and the third side of the second case cover.

6. The camera module protection structure as claimed in claim 5, wherein the connection manner of the first securing plate with the first and third sides is riveting or adhesion.

7. The camera module protection structure as claimed in claim 4, further comprising at least one second securing plate disposed on the other side of the case opposite to the first securing plate, the second securing plate being connected with the second side of the first case cover and the fourth side of the second case cover.

8. The camera module protection structure as claimed in claim 7, wherein the connection manner of the second securing plate with the second and fourth sides is riveting or adhesion.

9. The camera module protection structure as claimed in claim 1, further comprising a connector, the connector being disposed on the circuit board and connected to a circuit of an electronic apparatus.
